(19) United States
(12) Patent Application Publication
(10) Pub. No.: US 2024/0176254 A1
(43) Pub. Date: May 30, 2024

(54) CLAMP ELECTRODE MODIFICATION FOR IMPROVED OVERLAY

(71) Applicant: ASML Netherlands B.V., Veldhoven (NL)

(72) Inventors: Keane Michael LEVY, Wilton, CT (US); Sotrios LYRINTZIS, Danbury, CT (US); Maham AFTAB, Danbury, CT (US); Seyed Mehdi SHEIKHOLESLAM-NOURI, Norwalk, CT (US); Tammo UITTERDIJK, Wilton, CT (US)

(73) Assignee: ASML Netherlands B.V., Veldhoven (NL)

(21) Appl. No.: 18/281,921

(22) PCT Filed: Mar. 17, 2022
(86) PCT No.: PCT/EP2022/057047

§ 371 Date: Sep. 13, 2023

Related U.S. Application Data
(60) Provisional application No. 63/162,759, filed on Mar. 18, 2021.

(51) Int. Cl. G03F 7/00; H01L 21/683

(52) U.S. Cl. CPC G03F 7/70708; G03F 7/70783; H01L 21/6833

(57) ABSTRACT

Systems, apparatuses, and methods are provided for manufacturing an electrostatic clamp. An example method can include forming a dielectric layer that includes a plurality of burls for supporting an object. The example method can further include forming an electrostatic layer that includes one or more electrodes. The example method can further include generating, using the electrostatic layer, an electrostatic force to electrostatically clamp the object to the plurality of burls in response to an application of one or more voltages to the one or more electrodes. In some aspects, a first magnitude of the electrostatic force in a first region of the dielectric layer can be different than a second magnitude of the electrostatic force in a second region of the dielectric layer. For example, the first magnitude and the second magnitude can be part of a linear, non-linear, or stepped (e.g., multi-level) electrostatic force gradient.

### CROSS-REFERENCE TO RELATED APPLICATIONS

This application claims priority of U.S. Provisional Patent Application No. 63/162,759, which was filed on Mar. 18, 2021, and which is incorporated herein in its entirety by reference.

### TECHNICAL FIELD

The present disclosure relates to electrostatic wafer clamps and methods for forming and modifying electrode structures included in electrostatic wafer clamps.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a substrate (e.g., a silicon wafer). Transfer of the pattern is typically via imaging onto a layer of radiation-sensitive material (e.g., resist) provided on the substrate. In general, a single substrate will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the substrate by imprinting the pattern onto the substrate.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are: 365 nm (i-line), 248 nm, and 193 nm in deep ultra violet (DUV) radiation systems; and 13.5 nm in extreme ultraviolet (EUV) radiation systems. EUV radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on substrates, for example, silicon wafers. A lithographic apparatus which uses EUV radiation having a wavelength within a range of 4 nm to 20 nm, for example 6.7 nm or 13.5 nm, can be used to form smaller features on a substrate than a lithographic apparatus which uses, for example, radiation with a wavelength of 193 nm.

It can be desirable to dictate and maintain tribological properties (e.g., friction, hardness, wear, etc.) on a surface of a substrate table. In some instances, a wafer clamp may be disposed on the surface of the substrate table. The wafer clamp may be, for example, a vacuum clamp for use in DUV radiation systems or an electrostatic clamp for use in EUV radiation systems. A substrate table, or a wafer clamp attached thereto, has a surface level tolerance that can be difficult to meet because of precision requirements of lithographic and metrology processes. Wafers (e.g., semiconductor substrates), being relatively thin (e.g., <1.0 millimeter (mm) thick) compared to a width of its surface area (e.g., >100.0 mm wide), are particularly sensitive to unevenness of the substrate table. Additionally, ultra-smooth surfaces in contact may become stuck together, which may present a problem when a substrate must be disengaged from the substrate table. To reduce the smoothness of the surface that interfaces with the wafer, the surface of the substrate table or wafer clamp may include burls formed by patterning and etching of a substrate. However, the wafer may sag in areas located between burls due to a combination of forces applied to the wafer by the burls, electrostatic clamping, backfill gas pressure, wafer stiffness, and gravity.

### SUMMARY

The present disclosure describes various aspects of systems, apparatuses, and methods for manufacturing an electrostatic clamp having a modified electrode layer for increasing wafer flatness and reducing overlay errors and inter-burl wafer sag.

In some aspects, the present disclosure describes an apparatus (e.g., a wafer clamp). The apparatus can include a dielectric layer that includes a plurality of burls configured to support an object. The apparatus can further include an electrostatic layer that includes one or more electrodes. The electrostatic layer can be configured to generate an electrostatic force to electrostatically clamp the object to the plurality of burls in response to an application of one or more voltages to the one or more electrodes. A first magnitude of the electrostatic force in a first region of the dielectric layer can be different than a second magnitude of the electrostatic force in a second region of the dielectric layer.

In some aspects, the electrostatic layer can include an electrostatic sheet that includes a plurality of apertures configured to receive the plurality of burls such that the plurality of burls line up with the plurality of apertures of the electrostatic sheet.

In some aspects, the apparatus can further include another dielectric layer, a first glass substrate that includes the dielectric layer, and a second glass substrate that includes the electrostatic layer and the another dielectric layer. In some aspects, the electrostatic layer can be disposed vertically between the dielectric layer and the another dielectric layer.

In some aspects, the first region of the dielectric layer can be disposed horizontally adjacent to one or more of the plurality of burls. In some aspects, the second region of the dielectric layer can be disposed horizontally between two or more of the plurality of burls but not horizontally adjacent to the two or more of the plurality of burls.

In some aspects, the electrostatic force can include an electrostatic clamp pressure. In some aspects, a first magnitude of the electrostatic clamp pressure in the first region of the dielectric layer can be greater than a second magnitude of the electrostatic clamp pressure in the second region of the dielectric layer.

In some aspects, a first portion of the one or more electrodes of the electrostatic layer can be disposed in a first horizontal plane. In some aspects, a second portion of the one or more electrodes of the electrostatic layer can be disposed in a second horizontal plane different from the first horizontal plane.

In some aspects, a first thickness of the first region of the dielectric layer can be greater than a second thickness of the second region of the dielectric layer.

In some aspects, the electrostatic layer can include an electrode disposed vertically adjacent to the first region of the dielectric layer. In some aspects, the electrostatic layer can include no electrode disposed vertically adjacent to the second region of the dielectric layer.

In some aspects, the present disclosure describes a method for manufacturing an apparatus (e.g., a wafer clamp). The method can include forming a dielectric layer that includes a plurality of burls for supporting an object. The method can further include forming an electrostatic layer that includes one or more electrodes. The method can further include generating, using the electrostatic layer, an electrostatic force to electrostatically clamp the object to the plurality of burls in response to an application of one or more voltages to the one or more electrodes. A first magnitude of the electrostatic force in a first region of the dielectric layer can be different than a second magnitude of the electrostatic force in a second region of the dielectric layer.

In some aspects, the forming of the electrostatic layer can include forming an electrostatic sheet that includes a plurality of apertures that receive the plurality of burls such that the plurality of burls line up with the plurality of apertures. In some aspects, the method can further include mounting the electrostatic sheet to the dielectric layer.

In some aspects, the forming of the dielectric layer can include forming the plurality of burls on a first glass substrate. In some aspects, the forming of the electrostatic layer can include forming the electrostatic layer on a second glass substrate. In some aspects, the method can further include mounting the electrostatic layer to the dielectric layer such that the electrostatic layer can be disposed vertically between the first glass substrate and the second glass substrate.

In some aspects, the method can further include disposing the first region of the dielectric layer horizontally adjacent to one or more of the plurality of burls. In some aspects, the method can further include disposing the second region of the dielectric layer horizontally between two or more of the plurality of burls but not horizontally adjacent to the two or more of the plurality of burls.

In some aspects, the electrostatic force can include an electrostatic clamp pressure. In some aspects, a first magnitude of the electrostatic clamp pressure in the first region of the dielectric layer can be greater than a second magnitude of the electrostatic clamp pressure in the second region of the dielectric layer.

In some aspects, the forming of the electrostatic layer can include forming a first portion of the one or more electrodes in a first horizontal plane. In some aspects, the forming of the electrostatic layer can include forming a second portion of the one or more electrodes in a second horizontal plane different from the first horizontal plane.

In some aspects, the forming of the dielectric layer can include forming the first region of the dielectric layer to a first thickness. In some aspects, the forming of the dielectric layer can further include forming the second region of the dielectric layer to a second thickness different from the first thickness.

In some aspects, the forming of the electrostatic layer can include forming a first electrode in a first area vertically adjacent to the first region of the dielectric layer. In some aspects, the forming of the electrostatic layer can further include removing, by laser irradiation, a second electrode from a second area vertically adjacent to the second region of the dielectric layer.

In some aspects, the present disclosure describes another method for manufacturing an apparatus (e.g., a method for modifying or refurbishing a wafer clamp). The method can include receiving a wafer clamp. The wafer clamp can include a dielectric layer that includes a plurality of burls configured to support an object. The wafer clamp can further include an electrostatic layer that includes one or more electrodes. The method can further include removing, by laser irradiation, one or more portions of the one or more electrodes of the electrostatic layer. The electrostatic layer can be configured to generate an electrostatic force to electrostatically clamp the object to the plurality of burls in response to an application of one or more voltages to the one or more electrodes. A first magnitude of the electrostatic force in a first region of the dielectric layer can be different than a second magnitude of the electrostatic force in a second region of the dielectric layer.

In some aspects, the first region of the dielectric layer can be disposed horizontally adjacent to one or more of the plurality of burls. In some aspects, the second region of the dielectric layer can be disposed horizontally between two or more of the plurality of burls but not horizontally adjacent to the two or more of the plurality of burls.

In some aspects, the electrostatic force can include an electrostatic clamp pressure. In some aspects, a first magnitude of the electrostatic clamp pressure in the first region of the dielectric layer can be greater than a second magnitude of the electrostatic clamp pressure in the second region of the dielectric layer.

In some aspects, the removing of the one or more portions of the one or more electrodes of the electrostatic layer can include removing, by laser irradiation, an electrode from an area vertically adjacent to the second region of the dielectric layer.

Further features, as well as the structure and operation of various aspects, are described in detail below with reference to the accompanying drawings. It is noted that the disclosure is not limited to the specific aspects described herein. Such aspects are presented herein for illustrative purposes only. Additional aspects will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the aspects of this disclosure and to enable a person skilled in the relevant art(s) to make and use the aspects of this disclosure.

FIG. 1A is a schematic illustration of an example reflective lithographic apparatus according to some aspects of the present disclosure.

FIG. 1B is a schematic illustration of an example transmissive lithographic apparatus according to some aspects of the present disclosure.

FIG. 2 is a more detailed schematic illustration of the reflective lithographic apparatus shown in FIG. 1A according to some aspects of the present disclosure.

FIG. 3 is a schematic illustration of an example lithographic cell according to some aspects of the present disclosure.

FIG. 4 is a schematic illustration of an example substrate stage according to some aspects of the present disclosure.

FIG. 5 is a schematic illustration of an example wafer clamp according to some aspects of the present disclosure.

FIG. 6 is a schematic illustration of another example wafer clamp according to some aspects of the present disclosure.

FIG. 7 is a schematic illustration of another example wafer clamp according to some aspects of the present disclosure.

FIGS. 8A, 8B, 8C, and 8D are schematic illustrations of another example wafer clamp according to some aspects of the present disclosure.

FIG. 9 is an example method for manufacturing an electrostatic clamp according to some aspects of the present disclosure or portion(s) thereof.

FIG. 10 is another example method for manufacturing an electrostatic clamp according to some aspects of the present disclosure or portion(s) thereof.

The features and advantages of the present disclosure will become more apparent from the detailed description set forth below when taken in conjunction with the drawings, in which like reference characters identify corresponding elements throughout. In the drawings, unless otherwise indicated, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) merely describe the present disclosure. The scope of the disclosure is not limited to the disclosed embodiment(s). The breadth and scope of the disclosure are defined by the claims appended hereto and their equivalents.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

Spatially relative terms, such as “beneath,” “below,” “lower,” “above,” “on,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

### Overview

In one example, lithographic apparatuses that use an EUV radiation source can require the EUV radiation beam path, or at least substantial parts of it, to be kept in vacuum during a lithographic operation. In these vacuum regions of the lithographic apparatus, an electrostatic clamp can be used to clamp an object, such as a patterning device (e.g., a mask or reticle) or a substrate (e.g., a wafer), to a structure of the lithographic apparatus, such as a patterning device table or a substrate table, respectively. An example electrostatic clamp can include an electrode at one surface of the electrostatic clamp with a plurality of burls disposed on the opposite surface of the electrostatic clamp. As the electrostatic clamp is energized (e.g., using a clamping voltage) and pulls the reticle or wafer in contact with the burls using a substantially uniform clamping force, the reticle or wafer may experience inter-burl sag in areas located in between the burls due to a combination of forces applied to the reticle or wafer by the burls, electrostatic clamping, backfill gas pressure, wafer stiffness, and gravity. Consequently, techniques are needed for changing the force that pulls on the reticle or wafer in between the burls without increasing number of burls, decreasing the inter-burl distance, adjusting back fill gas (BFG) pressure, or modifying the wafer, each of which can increase manufacturing complexity and processing times.

In contrast to these systems, the present disclosure provides methods for manufacturing or refurbishing an electrostatic clamp that decrease the force pulling on the reticle or wafer in between the burls without increasing number of burls, decreasing the inter-burl distance, adjusting BFG pressure, or modifying the wafer. In some aspects, the disclosure provides for wafer clamps having non-uniform clamping forces. For example, the clamping force can be higher in areas adjacent to the burls and lower in areas in between the burls. In some aspects, the disclosure provides for increasing wafer flatness by modifying the dielectric thickness (and, in turn, the clamping force) in particular regions of the wafer clamp. In some aspects, the disclosure provides for increasing wafer flatness by using laser irradiation to substantially remove the electrode (and, in turn, substantially eliminate the clamping force) in inter-burl regions of the wafer clamp.

In some aspects, the wafer clamp can have a lateral positioning of the electrode that is controlled to a micron level (e.g., where wafer flatness needs to be controlled to a nanometer level). In such aspects, the present disclosure provides for adjusting the ratio of dielectric (e.g., glass) to vacuum gap to adjust the clamping force. The “tunability” of this force can be dependent on the ratio of vacuum permittivity to the dielectric constants of the materials used to fabricate the wafer clamp.

There are many exemplary aspects to the systems, apparatuses, methods, and computer program products disclosed herein. For example, by adjusting dielectric thickness and electrode position, the example wafer clamps disclosed herein can tune and adjust the inter-burl clamping force without adjusting the clamping voltage. As a result, the example wafer clamps disclosed herein provide additional control (e.g., to adjust electrostatic pressure) to suit design specifications, increase wafer flatness, and reduce wafer sag, thereby increasing performance of the lithographic apparatus (e.g., by reducing overlay errors) while keeping the design simpler (e.g., without adding more electrodes) and, in some aspects, backwards compatible (e.g., reversible).

Before describing such aspects in more detail, however, it is instructive to present an example environment in which aspects of the present disclosure can be implemented.

### Example Lithographic Systems

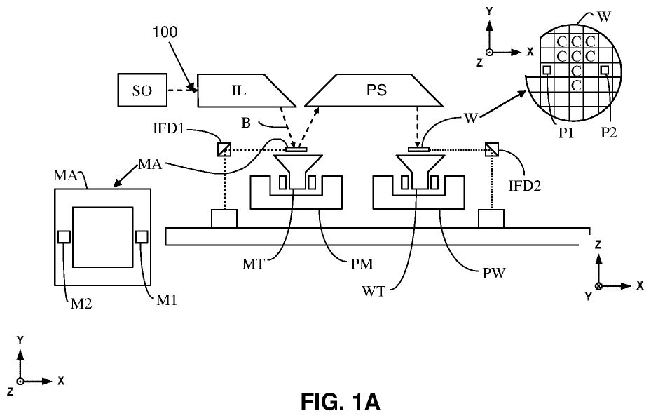

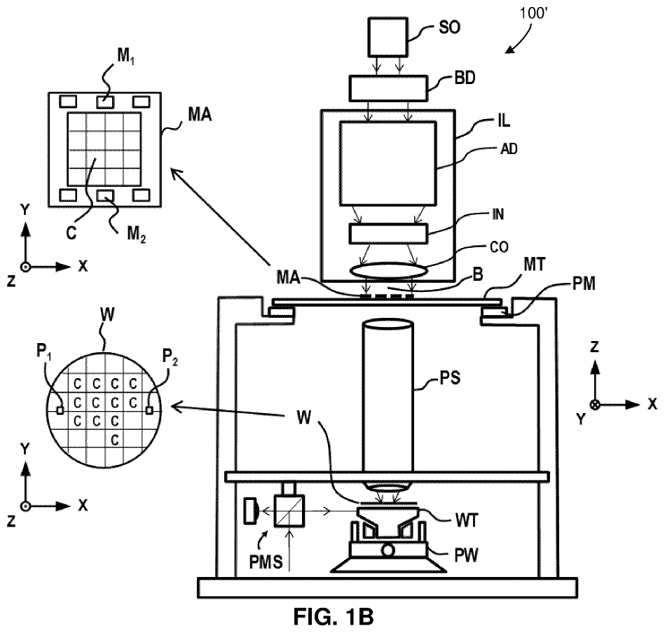

FIGS. 1A and 1B are schematic illustrations of a lithographic apparatus 100 and a lithographic apparatus 100′, respectively, in which aspects of the present disclosure can be implemented. As shown in FIGS. 1A and 1B, the lithographic apparatuses 100 and 100′ are illustrated from a point of view (e.g., a side view) that is normal to the XZ plane (e.g., the X-axis points to the right, the Z-axis points upward, and the Y-axis points into the page away from the viewer), while the patterning device MA and the substrate W are presented from additional points of view (e.g., a top view) that are normal to the XY plane (e.g., the X-axis points to the right, the Y-axis points upward, and the Z-axis points out of the page toward the viewer).

In some aspects, the lithographic apparatus 100 and/or the lithographic apparatus 100′ can include one or more of the following structures: an illumination system IL (e.g., an illuminator) configured to condition a radiation beam B (e.g., a deep ultra violet (DUV) radiation beam or an extreme ultra violet (EUV) radiation beam); a support structure MT (e.g., a mask table) configured to support a patterning device MA (e.g., a mask, a reticle, or a dynamic patterning device) and connected to a first positioner PM configured to accurately position the patterning device MA; and, a substrate holder such as a substrate table WT (e.g., a wafer table) configured to hold a substrate W (e.g., a resist-coated wafer) and connected to a second positioner PW configured to accurately position the substrate W. Lithographic apparatuses 100 and 100′ also have a projection system PS (e.g., a refractive projection lens system) configured to project a pattern imparted to the radiation beam B by patterning device MA onto a target portion C (e.g., a portion including one or more dies) of the substrate W. In lithographic apparatus 100, the patterning device MA and the projection system PS are reflective. In lithographic apparatus 100′, the patterning device MA and the projection system PS are transmissive.

In some aspects, in operation, the illumination system IL can receive a radiation beam from a radiation source SO (e.g., via a beam delivery system BD shown in FIG. 1B). The illumination system IL can include various types of optical structures, such as refractive, reflective, catadioptric, magnetic, electromagnetic, electrostatic, and other types of optical components, or any combination thereof, for directing, shaping, or controlling radiation. In some aspects, the illumination system IL can be configured to condition the radiation beam B to have a desired spatial and angular intensity distribution in its cross-section at a plane of the patterning device MA.

In some aspects, the support structure MT can hold the patterning device MA in a manner that depends on the orientation of the patterning device MA with respect to a reference frame, the design of at least one of the lithographic apparatuses 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

In some aspects, the patterning device MA can be transmissive (as in lithographic apparatus 100′ of FIG. 1B) or reflective (as in lithographic apparatus 100 of FIG. 1A). The patterning device MA can include various structures such as reticles, masks, programmable mirror arrays, programmable LCD panels, other suitable structures, or combinations thereof. Masks can include mask types such as binary, alternating phase shift, or attenuated phase shift, as well as various hybrid mask types. In one example, a programmable mirror array can include a matrix arrangement of small mirrors, each of which can be individually tilted so as to reflect an incoming radiation beam in different directions. The tilted mirrors can impart a pattern in the radiation beam B, which is reflected by a matrix of small mirrors.

The term “projection system” PS should be interpreted broadly and can encompass any type of projection system, including refractive, reflective, catadioptric, magnetic, anamorphic, electromagnetic, and electrostatic optical systems, or any combination thereof, as appropriate for the exposure radiation being used, and/or for other factors such as the use of an immersion liquid (e.g., on the substrate W) or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps. In addition, any use herein of the term “projection lens” can be interpreted, in some aspects, as synonymous with the more general term “projection system” PS.

In some aspects, the lithographic apparatus 100 and/or the lithographic apparatus 100′ can be of a type having two (e.g., “dual stage”) or more substrate tables WT and/or two or more mask tables). In such “multiple stage” machines, the additional substrate tables WT can be used in parallel, or preparatory steps can be carried out on one or more tables while one or more other substrate tables WT are being used for exposure. In one example, steps in preparation of a subsequent exposure of the substrate W can be carried out on the substrate W located on one of the substrate tables WT while another substrate W located on another of the substrate tables WT is being used for exposing a pattern on another substrate W. In some aspects, the additional table may not be a substrate table WT.

In some aspects, in addition to the substrate table WT, the lithographic apparatus 100 and/or the lithographic apparatus 100′ can include a measurement stage. The measurement stage can be arranged to hold a sensor. The sensor can be arranged to measure a property of the projection system PS, a property of the radiation beam B, or both. In some aspects, the measurement stage can hold multiple sensors. In some aspects, the measurement stage can move beneath the projection system PS when the substrate table WT is away from the projection system PS.

In some aspects, the lithographic apparatus 100 and/or the lithographic apparatus 100′ can also be of a type wherein at least a portion of the substrate can be covered by a liquid having a relatively high refractive index, e.g., water, so as to fill a space between the projection system PS and the substrate W. An immersion liquid can also be applied to other spaces in the lithographic apparatus, for example, between the patterning device MA and the projection system PS. Immersion techniques provide for increasing the numerical aperture of projection systems. The term “immersion” as used herein does not mean that a structure, such as a substrate, must be submerged in liquid, but rather only means that liquid is located between the projection system and the substrate during exposure. Various immersion techniques are described in U.S. Pat. No. 6,952,253, issued Oct. 4, 2005, and titled “LITHOGRAPHIC APPARATUS AND DEVICE MANUFACTURING METHOD,” which is incorporated by reference herein in its entirety.

Referring to FIGS. 1A and 1B, the illumination system IL receives a radiation beam B from a radiation source SO. The radiation source SO and the lithographic apparatus 100 or 100′ can be separate physical entities, for example, when the radiation source SO is an excimer laser. In such cases, the radiation source SO is not considered to form part of the lithographic apparatus 100 or 100′, and the radiation beam B passes from the radiation source SO to the illumination system IL with the aid of a beam delivery system BD (e.g., shown in FIG. 1B) including, for example, suitable directing mirrors and/or a beam expander. In other cases, the radiation source SO can be an integral part of the lithographic apparatus 100 or 100′, for example, when the radiation source SO is a mercury lamp. The radiation source SO and the illuminator IL, together with the beam delivery system BD, if required, can be referred to as a radiation system.

In some aspects, the illumination system IL can include an adjuster AD for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illumination system IL can include various other components, such as an integrator IN and a radiation collector CO (e.g., a condenser or collector optic). In some aspects, the illumination system IL can be used to condition the radiation beam B to have a desired uniformity and intensity distribution in its cross section.

Referring to FIG. 1A, in operation, the radiation beam B can be incident on the patterning device MA (e.g., a mask, reticle, programmable mirror array, programmable LCD panel, any other suitable structure or combination thereof), which can be held on the support structure MT (e.g., a mask table), and can be patterned by the pattern (e.g., design layout) present on the patterning device MA. In lithographic apparatus 100, the radiation beam B can be reflected from the patterning device MA. Having traversed (e.g., after being reflected from) the patterning device MA, the radiation beam B can pass through the projection system PS, which can focus the radiation beam B onto a target portion C of the substrate W or onto a sensor arranged at a stage.

In some aspects, with the aid of the second positioner PW and position sensor IFD2 (e.g., an interferometric device, linear encoder, or capacitive sensor), the substrate table WT can be moved accurately, e.g., so as to position different target portions C in the path of the radiation beam B. Similarly, the first positioner PM and another position sensor IFD1 (e.g., an interferometric device, linear encoder, or capacitive sensor) can be used to accurately position the patterning device MA with respect to the path of the radiation beam B.

In some aspects, patterning device MA and substrate W can be aligned using mask alignment marks M1 and M2 and substrate alignment marks P1 and P2. Although FIGS. 1A and 1B illustrate the substrate alignment marks P1 and P2 as occupying dedicated target portions, the substrate alignment marks P1 and P2 may be located in spaces between target portions. Substrate alignment marks P1 and P2 are known as scribe-lane alignment marks when they are located between the target portions C. Substrate alignment marks P1 and P2 can also be arranged in the target portion C area as in-die marks. These in-die marks can also be used as metrology marks, for example, for overlay measurements.

In some aspects, for purposes of illustration and not limitation, one or more of the figures herein can utilize a Cartesian coordinate system. The Cartesian coordinate system includes three axes: an X-axis; a Y-axis; and a Z-axis. Each of the three axes is orthogonal to the other two axes (e.g., the X-axis is orthogonal to the Y-axis and the Z-axis, the Y-axis is orthogonal to the X-axis and the Z-axis, the Z-axis is orthogonal to the X-axis and the Y-axis). A rotation around the X-axis is referred to as an Rx-rotation. A rotation around the Y-axis is referred to as an Ry-rotation. A rotation around about the Z-axis is referred to as an Rz-rotation. In some aspects, the X-axis and the Y-axis define a horizontal plane, whereas the Z-axis is in a vertical direction. In some aspects, the orientation of the Cartesian coordinate system may be different, for example, such that the Z-axis has a component along the horizontal plane. In some aspects, another coordinate system, such as a cylindrical coordinate system, can be used.

Referring to FIG. 1B, the radiation beam B is incident on the patterning device MA, which is held on the support structure MT, and is patterned by the patterning device MA. Having traversed the patterning device MA, the radiation beam B passes through the projection system PS, which focuses the beam onto a target portion C of the substrate W. In some aspects, the projection system PS can have a pupil conjugate to an illumination system pupil. In some aspects, portions of radiation can emanate from the intensity distribution at the illumination system pupil and traverse a mask pattern without being affected by diffraction at the mask pattern MP and create an image of the intensity distribution at the illumination system pupil.

The projection system PS projects an image MP′ of the mask pattern MP, where image MP′ is formed by diffracted beams produced from the mask pattern MP by radiation from the intensity distribution, onto a resist layer coated on the substrate W. For example, the mask pattern MP can include an array of lines and spaces. A diffraction of radiation at the array and different from zeroth-order diffraction generates diverted diffracted beams with a change of direction in a direction perpendicular to the lines. Reflected light (e.g., zeroth-order diffracted beams) traverses the pattern without any change in propagation direction. The zeroth-order diffracted beams traverse an upper lens or upper lens group of the projection system PS, upstream of the pupil conjugate of the projection system PS, to reach the pupil conjugate. The portion of the intensity distribution in the plane of the pupil conjugate and associated with the zeroth-order diffracted beams is an image of the intensity distribution in the illumination system pupil of the illumination system IL. In some aspects, an aperture device can be disposed at, or substantially at, a plane that includes the pupil conjugate of the projection system PS.

The projection system PS is arranged to capture, by means of a lens or lens group, not only the zeroth-order diffracted beams, but also first-order or first- and higher-order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the substrate W to create an image of the mask pattern MP at highest possible resolution and process window (e.g., usable depth of focus in combination with tolerable exposure dose deviations). In some aspects, astigmatism aberration can be reduced by providing radiation poles (not shown) in opposite quadrants of an illumination system pupil. Further, in some aspects, astigmatism aberration can be reduced by blocking the zeroth-order beams in the pupil conjugate of the projection system PS associated with radiation poles in opposite quadrants. This is described in more detail in U.S. Pat. No. 7,511,799, issued Mar. 31, 2009, and titled “LITHOGRAPHIC PROJECTION APPARATUS AND A DEVICE MANUFACTURING METHOD,” which is incorporated by reference herein in its entirety.

In some aspects, with the aid of the second positioner PW and a position measurement system PMS (e.g., including a position sensor such as an interferometric device, linear encoder, or capacitive sensor), the substrate table WT can be moved accurately, e.g., so as to position different target portions C in the path of the radiation beam B at a focused and aligned position. Similarly, the first positioner PM and another position sensor (e.g., an interferometric device, linear encoder, or capacitive sensor) (not shown in FIG. 1B) can be used to accurately position the patterning device MA with respect to the path of the radiation beam B (e.g., after mechanical retrieval from a mask library or during a scan). Patterning device MA and substrate W can be aligned using mask alignment marks M1 and M2 and substrate alignment marks P1 and P2.

In general, movement of the support structure MT can be realized with the aid of a long-stroke positioner (coarse positioning) and a short-stroke positioner (fine positioning), which form part of the first positioner PM. Similarly, movement of the substrate table WT can be realized using a long-stroke positioner and a short-stroke positioner, which form part of the second positioner PW. In the case of a stepper (as opposed to a scanner), the support structure MT can be connected to a short-stroke actuator only or can be fixed. Patterning device MA and substrate W can be aligned using mask alignment marks M1 and M2, and substrate alignment marks P1 and P2. Although the substrate alignment marks (as illustrated) occupy dedicated target portions, they can be located in spaces between target portions (e.g., scribe-lane alignment marks). Similarly, in situations in which more than one die is provided on the patterning device MA, the mask alignment marks M1 and M2 can be located between the dies.

Support structure MT and patterning device MA can be in a vacuum chamber V, where an in-vacuum robot can be used to move patterning devices such as a mask in and out of vacuum chamber. Alternatively, when support structure MT and patterning device MA are outside of the vacuum chamber, an out-of-vacuum robot can be used for various transportation operations, similar to the in-vacuum robot. In some instances, both the in-vacuum and out-of-vacuum robots need to be calibrated for a smooth transfer of any payload (e.g., a mask) to a fixed kinematic mount of a transfer station.

In some aspects, the lithographic apparatuses 100 and 100′ can be used in at least one of the following modes:

1. In step mode, the support structure MT and the substrate table WT are kept essentially stationary, while an entire pattern imparted to the radiation beam B is projected onto a target portion C at one time (e.g., a single static exposure). The substrate table WT is then shifted in the X and/or Y direction so that a different target portion C can be exposed.

2. In scan mode, the support structure MT and the substrate table WT are scanned synchronously while a pattern imparted to the radiation beam B is projected onto a target portion C (e.g., a single dynamic exposure). The velocity and direction of the substrate table WT relative to the support structure MT (e.g., mask table) can be determined by the (de-)magnification and image reversal characteristics of the projection system PS.

3. In another mode, the support structure MT is kept substantially stationary holding a programmable patterning device MA, and the substrate table WT is moved or scanned while a pattern imparted to the radiation beam B is projected onto a target portion C. A pulsed radiation source SO can be employed and the programmable patterning device is updated as required after each movement of the substrate table WT or in between successive radiation pulses during a scan. This mode of operation can be readily applied to maskless lithography that utilizes a programmable patterning device MA, such as a programmable mirror array.

In some aspects, the lithographic apparatuses 100 and 100′ can employ combinations and/or variations of the above-described modes of use or entirely different modes of use.

In some aspects, as shown in FIG. 1A, the lithographic apparatus 100 can include an EUV source configured to generate an EUV radiation beam B for EUV lithography. In general, the EUV source can be configured in a radiation source SO, and a corresponding illumination system IL can be configured to condition the EUV radiation beam B of the EUV source.

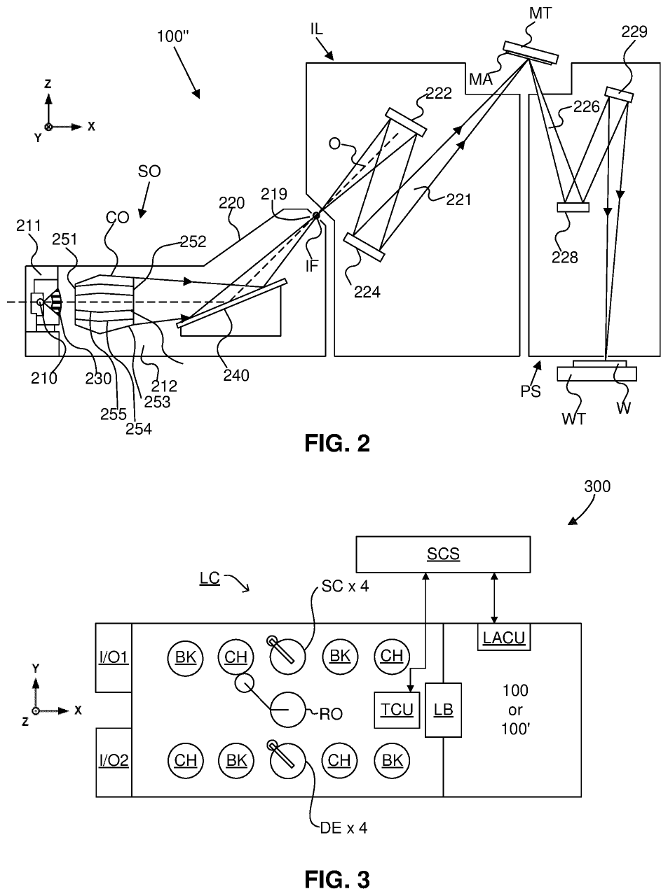

FIG. 2 shows the lithographic apparatus 100 in more detail, including the radiation source SO (e.g., a source collector apparatus), the illumination system IL, and the projection system PS. As shown in FIG. 2, the lithographic apparatus 100 is illustrated from a point of view (e.g., a side view) that is normal to the XZ plane (e.g., the X-axis points to the right and the Z-axis points upward).

The radiation source SO is constructed and arranged such that a vacuum environment can be maintained in an enclosing structure 220. The radiation source SO includes a source chamber 211 and a collector chamber 212 and is configured to produce and transmit EUV radiation. EUV radiation can be produced by a gas or vapor, for example xenon (Xe) gas, lithium (Li) vapor, or tin (Sn) vapor in which an EUV radiation emitting plasma 210 is created to emit radiation in the EUV range of the electromagnetic spectrum. The EUV radiation emitting plasma 210, at least partially ionized, can be created by, for example, an electrical discharge or a laser beam. Partial pressures of, for example, about 10.0 pascals (Pa) of Xe gas, Li vapor, Sn vapor, or any other suitable gas or vapor can be used for efficient generation of the radiation. In some aspects, a plasma of excited tin is provided to produce EUV radiation.

The radiation emitted by the EUV radiation emitting plasma 210 is passed from the source chamber 211 into the collector chamber 212 via an optional gas barrier or contaminant trap 230 (e.g., in some cases also referred to as contaminant barrier or foil trap), which is positioned in or behind an opening in the source chamber 211. The contaminant trap 230 can include a channel structure. Contaminant trap 230 can also include a gas barrier or a combination of a gas barrier and a channel structure. The contaminant trap 230 further indicated herein at least includes a channel structure.

The collector chamber 212 can include a radiation collector CO (e.g., a condenser or collector optic), which can be a so-called grazing incidence collector. Radiation collector CO has an upstream radiation collector side 251 and a downstream radiation collector side 252. Radiation that traverses radiation collector CO can be reflected off a grating spectral filter 240 to be focused in a virtual source point IF. The virtual source point IF is commonly referred to as the intermediate focus, and the source collector apparatus is arranged such that the virtual source point IF is located at or near an opening 219 in the enclosing structure 220. The virtual source point IF is an image of the EUV radiation emitting plasma 210. The grating spectral filter 240 can be used to suppress infrared (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the radiation beam 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination system IL and projection system PS. Optionally, the grating spectral filter 240 can be present depending upon the type of lithographic apparatus. Further, there can be more mirrors present than those shown in the FIG. 2. For example, there can be one to six additional reflective elements present in the projection system PS than shown in FIG. 2.

Radiation collector CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a radiation collector CO of this type is preferably used in combination with a discharge produced plasma (DPP) source.

### Example Lithographic Cell

FIG. 3 shows a lithographic cell 300, also sometimes referred to a lithocell or cluster. As shown in FIG. 3, the lithographic cell 300 is illustrated from a point of view (e.g., a top view) that is normal to the XY plane (e.g., the X-axis points to the right and the Y-axis points upward).

Lithographic apparatus 100 or 100′ can form part of lithographic cell 300. Lithographic cell 300 can also include one or more apparatuses to perform pre- and post-exposure processes on a substrate. For example, these apparatuses can include spin coaters SC to deposit resist layers, developers DE to develop exposed resist, chill plates CH, and bake plates BK. A substrate handler RO (e.g., a robot) picks up substrates from input/output ports I/O1 and I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Substrate Stage

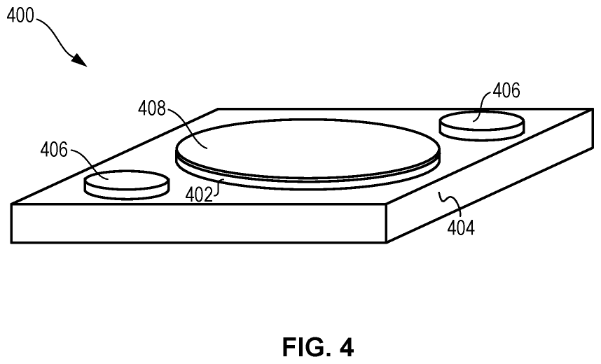

FIG. 4 shows a schematic illustration of an example substrate stage 400, according to some aspects of the present disclosure. In some aspects, the example substrate stage 400 can include a substrate table 402, a support block 404, one or more sensor structures 406, any other suitable component, or any combination thereof. In some aspects, substrate table 402 can include a clamp (e.g., a wafer clamp, a reticle clamp, an electrostatic clamp, or the like) to hold a substrate 408. In some aspects, each of one or more sensor structures 406 can include a transmission image sensor (TIS) plate. In some aspects, the TIS plate is a sensor unit that includes one or more sensors and/or markers for use in a TIS sensing system used for accurate positioning of the wafer relative to the position of a projection system (e.g., projection system PS described with reference to FIGS. 1A, 1B, and 2) and a mask (e.g., patterning device MA described with reference to FIGS. 1A, 1B, and 2) of a lithographic apparatus (e.g., lithographic apparatus 100 and lithographic apparatus 100′ described with reference to FIGS. 1A, 1B, and 2). While TIS plates are shown here for illustration, aspects herein are not limited to any particular sensor. Substrate table 402 can be disposed on support block 404. One or more sensor structures 406 can be disposed on support block 404.

In some aspects, substrate 408 can be disposed on substrate table 402 when the example substrate stage 400 supports the substrate 408.

The terms “flat,” “flatness” or the like can be used herein to describe structures in relation to a general plane of a surface. For example, a bent or unleveled surface can be one that does not conform to a flat plane. Protrusions and recesses on a surface can also be characterized as deviations from a “flat” plane.

The terms “smooth,” “roughness” or the like, can be used herein to refer to a local variation, microscopic deviations, graininess, or texture of a surface. For example, the term “surface roughness” can refer to microscopic deviations of the surface profile from a mean line or plane. The deviations are generally measured (in unit of length) as an amplitude parameter, such as root mean squared (RMS) or arithmetical mean deviation (Ra) (e.g., 1 nm RMS).

In some aspects, the surface of the substrate tables mentioned above (e.g., substrate table WT in FIGS. 1A and 1B, substrate table 402 in FIG. 4) can be flat or burled. When the surface of a substrate table is flat, any particulates or contaminants stuck between the substrate table and a wafer can cause the contaminant to print through the wafer, causing lithography errors in its vicinity. Consequently, contaminants reduce device yield rates and increase production costs.

In some aspects, burls are disposed on substrate tables help to reduce the undesirable effects of a flat substrate table. In some aspects, when a wafer is clamped to a burled substrate table, empty spaces are available in the regions where the wafer does not contact the substrate table. The empty spaces can function as pockets for contaminants so as to prevent printing errors. In some aspects, contaminants located on the burls are more likely to become crushed due to the increased load caused by the burls. Crushing contaminants can help mitigate print-through errors as well. In some aspects, the combined surface area of the burls can be approximately one percent to five percent of the surface area of the substrate table. In some aspects, surface area of the burls refers to the surfaces that come into contact with the wafer (e.g., not including the side walls); and surface area of the substrate table refers to the span of surface of the substrate table where the burls reside (e.g., not including the lateral or back side of the substrate table). In some aspects, when the wafer is clamped onto the burled substrate table, the load is increased by 100 fold as compared to a flat substrate table, which is enough to crush most contaminants. Though the example here uses a substrate table, the example is not intended to be limiting. For example, aspects of the present disclosure can be implemented on reticle tables, for a variety of clamping structures (e.g., electrostatic clamps, clamping membranes), and in a variety of lithographic systems (e.g., DUV, EUV).

In some aspects, the burl-to-wafer interface governs the functional performance of the substrate table. When the surface of a substrate table is smooth, an adhesion force can develop between the smooth surface of the substrate table and the smooth surface of a wafer. The phenomenon where two smooth surfaces in contact cling together is known as wringing. Wringing can cause issues (e.g., overlay issues) in device fabrication due to high friction and in-plane stresses in the wafer (it is optimal to have the wafer glide easily during alignment).

### Example Wafer Clamps

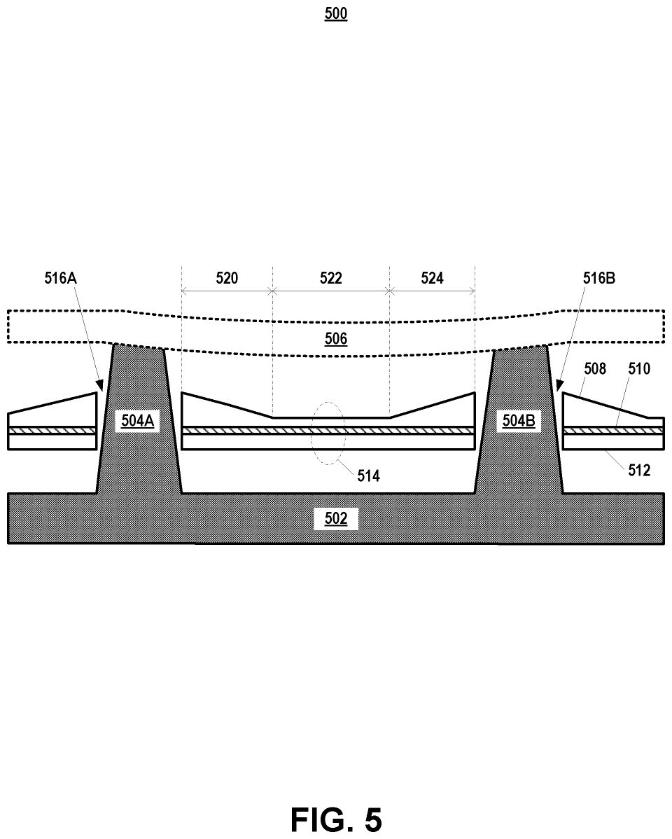

FIG. 5 is a schematic illustration of an example wafer clamp 500 (e.g., an electrostatic clamp) according to some aspects of the present disclosure. In some aspects, the example wafer clamp 500 can include a dielectric layer 502 that includes a plurality of burls 504 (including, but not limited to, burl 504A and burl 504B) configured to support an object 506 (e.g., a substrate). In some aspects, the example wafer clamp 500 can further include an electrostatic layer 508 that includes one or more electrodes 510.

In some aspects, the electrostatic layer 508 can be configured to generate an electrostatic force to electrostatically clamp the object 506 to the plurality of burls 504 in response to an application of one or more voltages to the one or more electrodes 510. In some aspects, a magnitude of the electrostatic force in a region 520 or a region 524 of the dielectric layer 502 can be different than a magnitude of the electrostatic force in a region 522 of the dielectric layer 502. For example, the example wafer clamp 500 can have multiple electrostatic force gradients (e.g., three gradients): (i) a negative electrostatic force gradient in region 520 (e.g., the magnitude of the electrostatic force can decrease from left (near burl 504A) to right (near region 522) as the thickness of electrostatic layer 508 decreases from left to right in region 520); (ii) a substantially zero electrostatic force gradient in region 522 (e.g., the magnitude of the electrostatic force can be substantially constant from left (near region 520) to right (near region 524) as the thickness of electrostatic layer 508 remains substantially constant from left to right in region 522, and equal to about the minimum value of the magnitude of the electrostatic force in region 520 and region 524); and (iii) a positive electrostatic force gradient in region 524 (e.g., the magnitude of the electrostatic force can increase from left (near region 522) to right (near burl 504B) as the thickness of electrostatic layer 508 increases from left to right in region 524).

In some aspects, the region 520 can be disposed horizontally adjacent to burl 504A, and the region 524 can be disposed horizontally adjacent to burl 504B. In some aspects, the region 522 can be disposed horizontally between burl 504A and burl 504B but not horizontally adjacent to burl 504A or burl 504B. In some aspects, the electrostatic force can include an electrostatic clamp pressure. In some aspects, a magnitude of the electrostatic clamp pressure in the region 520 or the region 524 can be greater than a magnitude of the electrostatic clamp pressure in the region 522. For example, the electrostatic clamp pressure in region 520, region 522, and region 524 can be a pressure gradient.

In some aspects, the electrostatic layer 508 can include, or be included in, an electrostatic sheet 514. In some aspects, the electrostatic sheet 514 can include the electrostatic layer 508, the one or more electrodes 510, an electrostatic layer 512, and a plurality of apertures 516 (including, but not limited to, aperture 516A and aperture 516B) configured to receive the plurality of burls 504 such that the plurality of burls 504 line up with the plurality of apertures 516 of the electrostatic sheet 514. In some aspects, the one or more electrodes 510 can be disposed vertically between the electrostatic layer 508 and the electrostatic layer 512.

In some aspects, the term “electrostatic layer” as used herein can refer to one or more dielectric layers disposed vertically adjacent to an electrically conductive layer (e.g., an electrode layer such as the one or more electrodes 510). In such aspects, the electrostatic layer 508, the electrostatic layer 512, any other electrostatic layer disclosed herein, or a combination thereof can be a dielectric layer.

In some aspects, by adjusting dielectric thickness and electrode position, the example wafer clamp 500 can tune and adjust the force, pressure, or both without adjusting the voltage. As a result, the example wafer clamp 500 provides additional control (e.g., to adjust electrostatic pressure) to suit design specifications, increase wafer flatness, and reduce wafer sag (e.g., as shown in object 506), thereby increasing performance of the lithographic apparatus (e.g., by reducing overlay errors) while keeping the design simpler (e.g., without adding more electrodes).

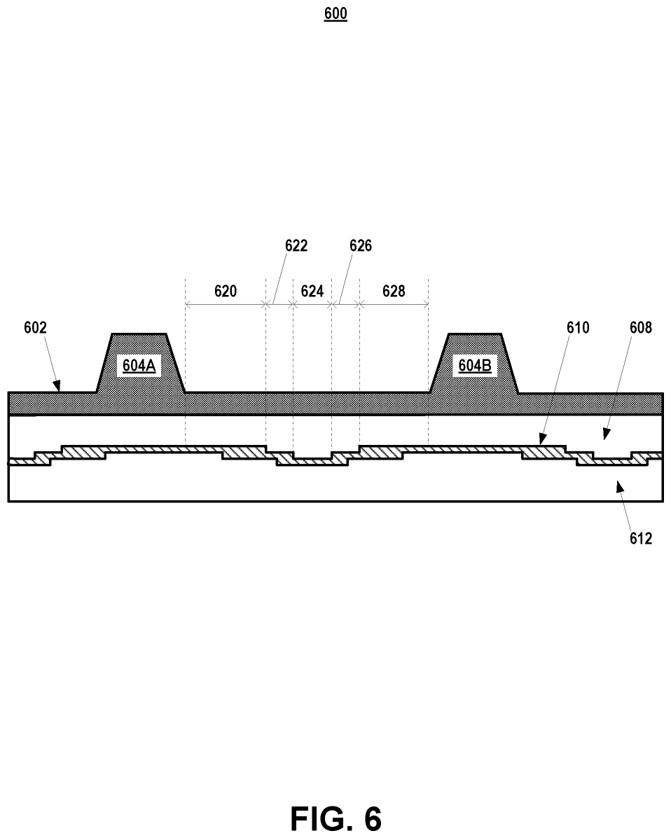

FIG. 6 is a schematic illustration of an example wafer clamp 600 (e.g., an electrostatic clamp) according to some aspects of the present disclosure. In some aspects, the example wafer clamp 600 can include a dielectric layer 602 that includes a plurality of burls 604 (including, but not limited to, burl 604A and burl 604B) configured to support an object (e.g., a substrate). In some aspects, the example wafer clamp 600 can further include an electrostatic layer 608 that includes one or more electrodes 610 fabricated (e.g., by depositing or growing, and then patterning and etching) according to a multi-level stepped structure. In one illustrative and non-limiting example, the one or more electrodes 610 can include a contour electrode fabricated as a stepped coating (e.g., using multiple coating runs to generate the electrode) before bonding an electrostatic sheet.

In some aspects, the electrostatic layer 608 can be configured to generate an electrostatic force to electrostatically clamp the object to the plurality of burls 604 in response to an application of one or more voltages to the one or more electrodes 610. In some aspects, a magnitude of the electrostatic force in a region 620 or a region 628 of the dielectric layer 602 can be different than a magnitude of the electrostatic force in a region 622, a region 624, or a region 626 of the dielectric layer 602. For example, the example wafer clamp 600 can have multiple electrostatic force zones (e.g., three zones): (i) a first electrostatic force zone in region 620 and region 628; (ii) a second electrostatic force zone in region 622 and region 626; and (iii) a third electrostatic force zone in region 624. In some aspects, the magnitude of the electrostatic force in the first electrostatic force zone can be greater than the magnitude of the electrostatic force in the second electrostatic force zone, and the magnitude of the electrostatic force in the second electrostatic force zone can be greater than the magnitude of the electrostatic force in the third electrostatic force zone.

In some aspects, the region 620 can be disposed horizontally adjacent to burl 604A, and the region 628 can be disposed horizontally adjacent to burl 604B. In some aspects, the region 622, the region 624, and the region 626 can be disposed horizontally between burl 604A and burl 604B but not horizontally adjacent to burl 604A or burl 604B. In some aspects, the electrostatic force can include an electrostatic clamp pressure. In some aspects, a magnitude of the electrostatic clamp pressure in the region 620 or the region 628 can be greater than a magnitude of the electrostatic clamp pressure in the region 622, the region 624, or the region 626. In some aspects, a magnitude of the electrostatic clamp pressure in the region 622 or the region 626 can be greater than a magnitude of the electrostatic clamp pressure in the region 624.

In some aspects, the example wafer clamp 600 can further include a dielectric layer 612, a first glass substrate that includes the dielectric layer 602, and a second glass substrate that includes the electrostatic layer 608, the one or more electrodes 610, and the dielectric layer 612. In some aspects, the electrostatic layer 608 can be disposed vertically between the dielectric layer 602 and the dielectric layer 612.

In some aspects, a first portion of the one or more electrodes 610 can be disposed in a first horizontal plane as shown in region 620 and region 628. In some aspects, a second portion of the one or more electrodes 610 can be disposed in a second horizontal plane as shown in region 622 and region 626. In some aspects, a third portion of the one or more electrodes 610 can be disposed in a second horizontal plane as shown in region 624. In some aspects, the first horizontal plane can be disposed closer to the dielectric layer 602 than the second horizontal plane, and the second horizontal plane can be disposed closer to the dielectric layer 602 than the third horizontal plane.

In some aspects, by adjusting dielectric thickness and electrode position, the example wafer clamp 600 can tune and adjust the force, pressure, or both without adjusting the voltage. As a result, the example wafer clamp 600 provides additional control (e.g., to adjust electrostatic pressure) to suit design specifications, increase wafer flatness, and reduce wafer sag, thereby increasing performance of the lithographic apparatus (e.g., by reducing overlay errors) while keeping the design simpler (e.g., without adding more electrodes).

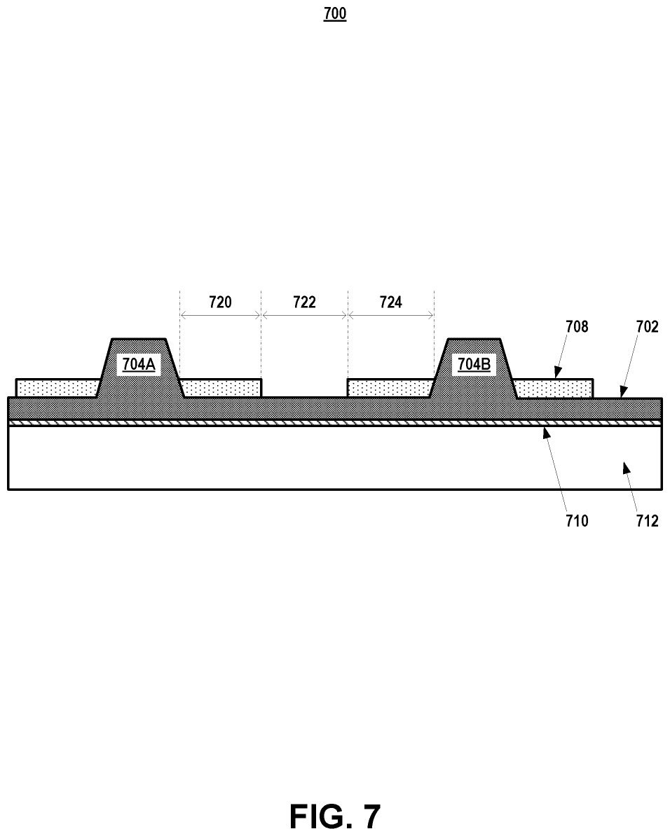

FIG. 7 is a schematic illustration of an example wafer clamp 700 (e.g., an electrostatic clamp) according to some aspects of the present disclosure. In some aspects, the example wafer clamp 700 can include a dielectric layer 702 that includes a plurality of burls 704 (including, but not limited to, burl 704A and burl 704B) configured to support an object (e.g., a substrate). In some aspects, the example wafer clamp 700 can further include an electrostatic layer 712 that includes one or more electrodes 710.

In some aspects, the electrostatic layer 712 can be configured to generate an electrostatic force to electrostatically clamp the object to the plurality of burls 704 in response to an application of one or more voltages to the one or more electrodes 710. In some aspects, a magnitude of the electrostatic force in a region 720 or a region 724 of the dielectric layer 702 can be different than a magnitude of the electrostatic force in a region 722 of the dielectric layer 702. For example, the example wafer clamp 700 can have multiple electrostatic force zones (e.g., two zones): (i) a first electrostatic force zone in region 720 and region 724; and (ii) a second electrostatic force zone in region 722. In some aspects, the magnitude of the electrostatic force in the first electrostatic force zone can be greater than the magnitude of the electrostatic force in the second electrostatic force zone.

In some aspects, the region 720 can be disposed horizontally adjacent to burl 704A, and the region 724 can be disposed horizontally adjacent to burl 704B. In some aspects, the region 722 can be disposed horizontally between burl 704A and burl 704B but not horizontally adjacent to burl 704A or burl 704B. In some aspects, the electrostatic force can include an electrostatic clamp pressure. In some aspects, a magnitude of the electrostatic clamp pressure in the region 720 or the region 724 can be greater than a magnitude of the electrostatic clamp pressure in the region 722.

In some aspects, the example wafer clamp 700 can include a first glass substrate that includes the dielectric layer 702 and a second glass substrate that includes the one or more electrodes 710, and the dielectric layer 712. In some aspects, the one or more electrodes 710 can be disposed vertically between the dielectric layer 702 and the dielectric layer 712.

In some aspects, a thickness of the dielectric layer 702 in the region 720 or the region 724 (e.g., the combined thickness of the dielectric layer 702 and the dielectric layer 708) can be greater than a thickness of the dielectric layer 702 in the region 722. For example, the forming of the dielectric layer 702 can include depositing (or thermally growing) and then patterning and etching a dielectric layer 708 (e.g., an SiO₂ layer) on top of the dielectric layer 702 to form the increased thickness shown in region 720 and region 724, and further to form the decreased thickness shown in region 722. In some aspects, coating additional dielectric in the region 720 and the region 724 can be desirable because the dielectric polarization of the dielectric material (e.g., glass) can be substantially greater than vacuum.

In some aspects, by adjusting dielectric thickness and electrode position, the example wafer clamp 700 can tune and adjust the force, pressure, or both without adjusting the voltage. As a result, the example wafer clamp 700 provides additional control (e.g., to adjust electrostatic pressure) to suit design specifications, increase wafer flatness, and reduce wafer sag, thereby increasing performance of the lithographic apparatus (e.g., by reducing overlay errors) while keeping the design simpler (e.g., without adding more electrodes) and backwards compatible (e.g., reversible).

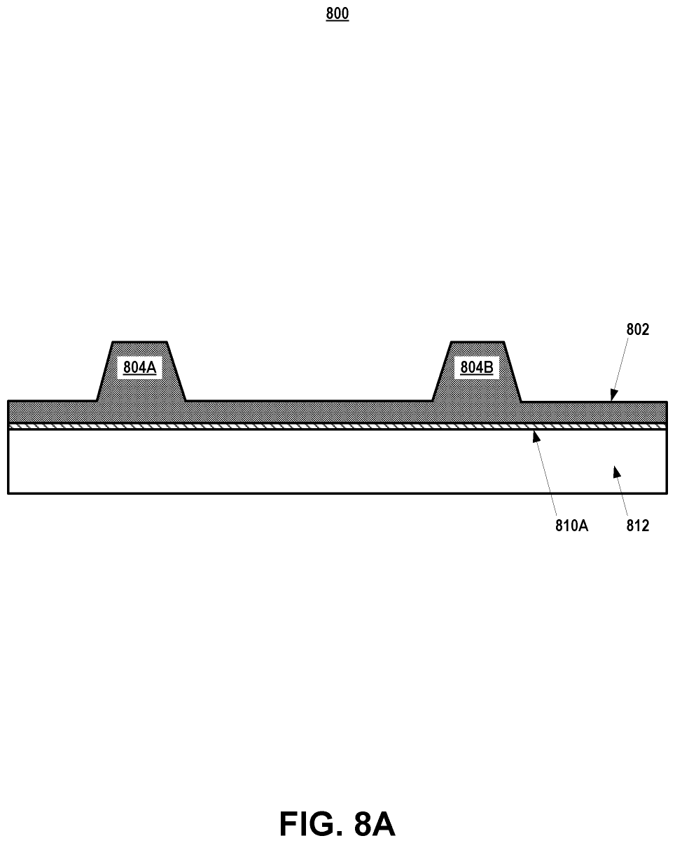

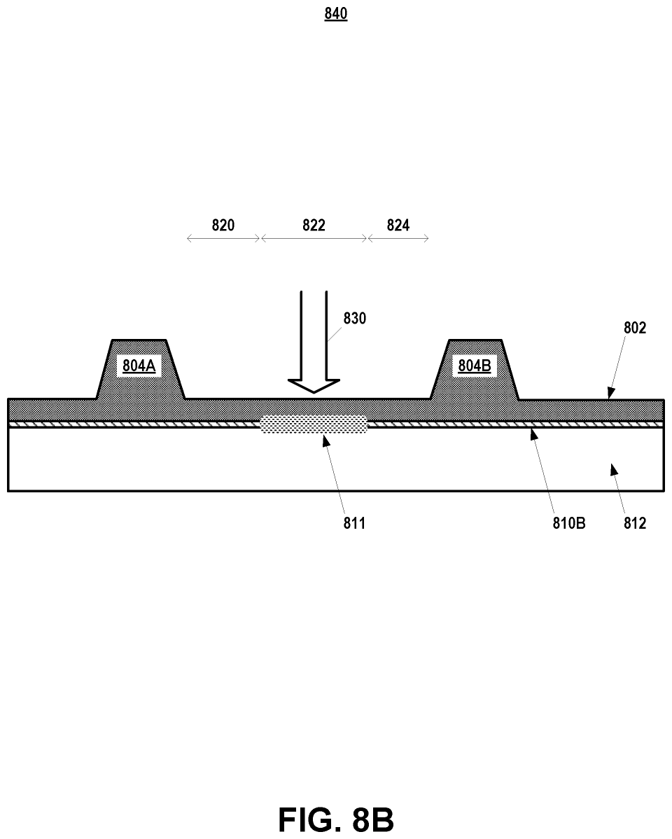

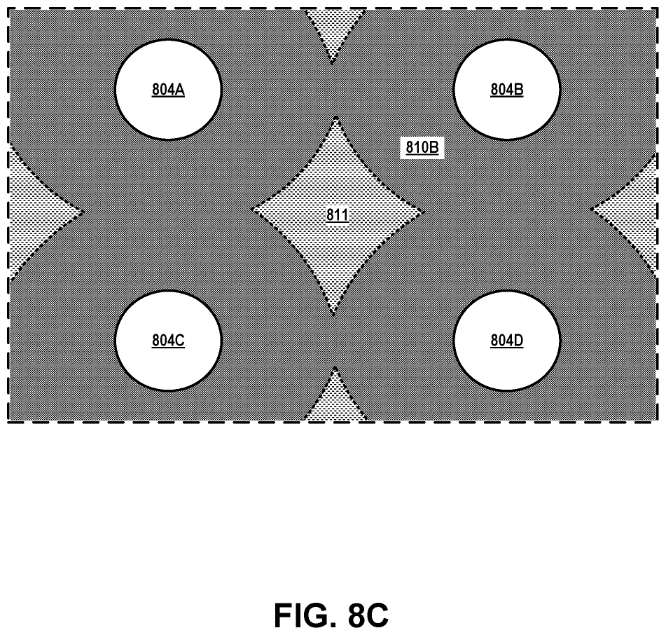

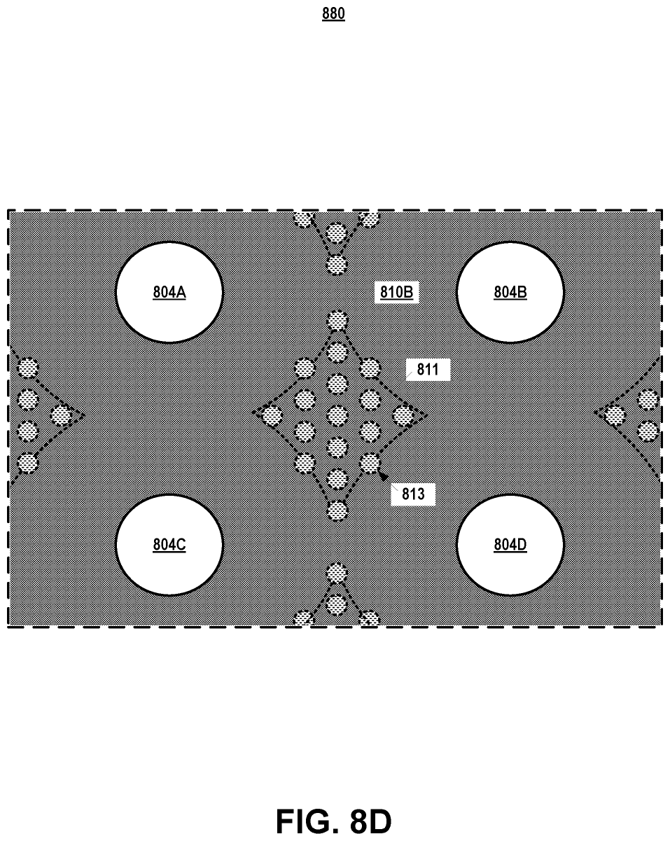

FIGS. 8A, 8B, 8C, and 8D are schematic illustrations of an example wafer clamp 800 (e.g., an electrostatic clamp) according to some aspects of the present disclosure.

As shown in FIG. 8A, in some aspects, the example wafer clamp 800 can include a dielectric layer 802 that includes a plurality of burls 804 (including, but not limited to, burl 804A and burl 804B) configured to support an object (e.g., a substrate). In some aspects, the example wafer clamp 800 can further include an electrostatic layer 812 that includes one or more electrodes 810. In some aspects, the example wafer clamp 800 can include a first glass substrate that includes the dielectric layer 802 and a second glass substrate that includes the one or more electrodes 810, and the dielectric layer 812. In some aspects, the one or more electrodes 810 can be disposed vertically between the dielectric layer 802 and the dielectric layer 812.

As shown in FIG. 8B, in some aspects, the example wafer clamp 800 may be modified to form the example wafer clamp 840 by applying laser irradiation 830 to area 811 of the one or more electrodes 810A. As a result. the electrostatic layer 812 of the example wafer clamp 840 can include an electrode 810B disposed vertically adjacent to the region 820 and the region 824 of the dielectric layer 802, and substantially no electrode disposed vertically adjacent to the region 822 of the dielectric layer 802 (e.g., in area 811). In some aspects, the electrode in area 811 disposed vertically adjacent to region 822 can be removed by laser irradiation 830 (e.g., utilizing laser structuring after the bonding of an electrostatic sheet to locally remove the electrode in area 811). In some aspects where the one or more electrodes 810 include a conductive chromium (Cr) electrode layer, the laser irradiation 830 can convert the Cr electrode layer in the vicinity of area 811 into an insulating chromium oxide (CrO) area that substantially cannot provide an electrostatic force when a voltage is applied to the one or more electrodes 810B.

In some aspects, the electrostatic layer 812 can be configured to generate an electrostatic force to electrostatically clamp the object to the plurality of burls 804 in response to an application of one or more voltages to the one or more electrodes 810. In some aspects, a magnitude of the electrostatic force in a region 820 or a region 824 of the dielectric layer 802 can be different than a magnitude of the electrostatic force in a region 822 of the dielectric layer 802. For example, the example wafer clamp 800 can have multiple electrostatic force zones (e.g., two zones): (i) an electrostatic force “on” zone in region 820 and region 824 (e.g., which have an electrode 810B and a clamping force); and (ii) an electrostatic force “off” zone in region 822 (e.g., which has substantially no functional electrode due to the laser irradiation 830 of area 811, and thus has substantially no clamping force). In some aspects, the magnitude of the electrostatic force in the first electrostatic force zone can be greater than the magnitude of the electrostatic force in the second electrostatic force zone.

In some aspects, the region 820 can be disposed horizontally adjacent to burl 804A, and the region 824 can be disposed horizontally adjacent to burl 804B. In some aspects, the region 822 can be disposed horizontally between burl 804A and burl 804B but not horizontally adjacent to burl 804A or burl 804B. In some aspects, the electrostatic force can include an electrostatic clamp pressure. In some aspects, a magnitude of the electrostatic clamp pressure in the region 820 or the region 824 can be greater than a magnitude of the electrostatic clamp pressure in the region 822.

FIG. 8C provides a schematic illustration of a planar view (e.g., a top view) of the example wafer clamp 840. In some aspects, area 811 provides substantially no electrostatic force when a voltage is applied to the one or more electrodes 810B and thus reduces wafer sag in the area between burl 804A, 804B, 804C, and 804D.

FIG. 8D provides a schematic illustration of a planar view (e.g., a top view) of an example wafer clamp 880. As shown in FIG. 8D, the area 811 can be formed by applying laser irradiation in the form of a plurality of dots 813 rather than a continuous area (e.g., as shown in FIGS. 8B and 8C). In some aspects, each of the plurality of dots 813 provides substantially no electrostatic force when a voltage is applied to the one or more electrodes 810B and thus reduces wafer sag in the area between burl 804A, 804B, 804C, and 804D.

In some aspects, by adjusting dielectric thickness and electrode position, the example wafer clamp 800 can tune and adjust the force, pressure, or both without adjusting the voltage. As a result, the example wafer clamp 800 provides additional control (e.g., to adjust electrostatic pressure) to suit design specifications, increase wafer flatness, and reduce wafer sag, thereby increasing performance of the lithographic apparatus (e.g., by reducing overlay errors) while keeping the design simpler (e.g., without adding more electrodes).

### Example Processes for Manufacturing an Electrostatic Clamp

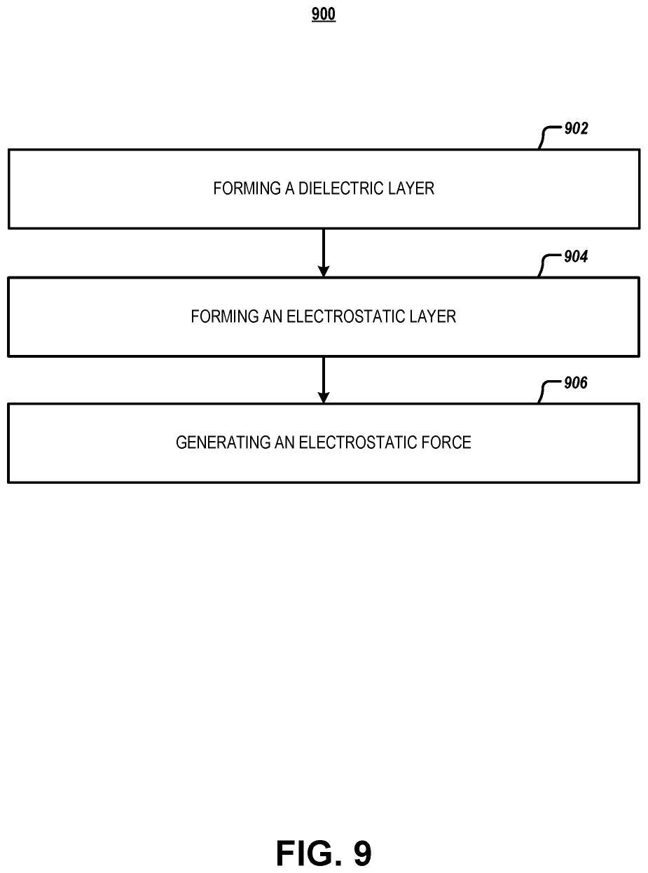

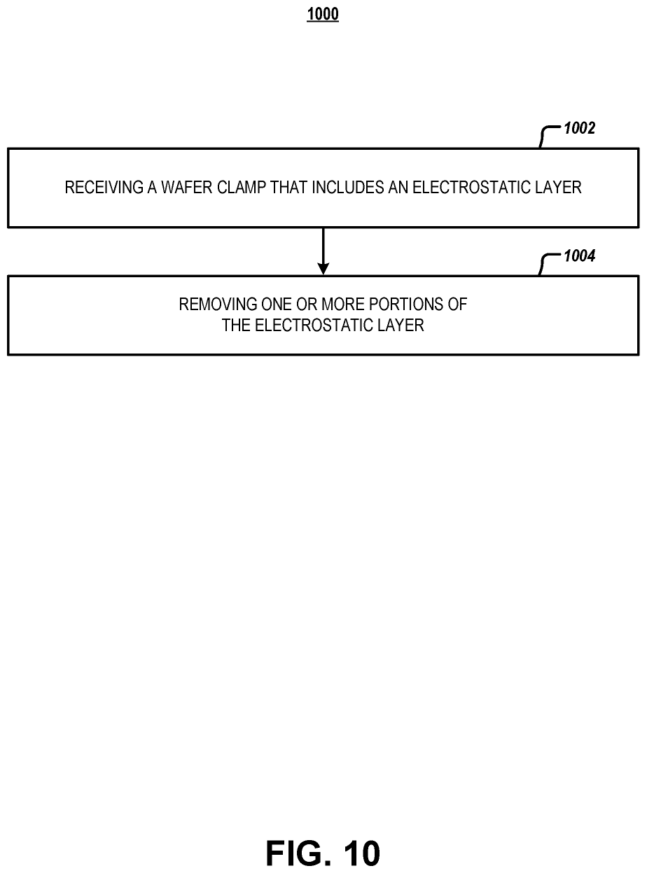

FIG. 9 is an example method 900 for manufacturing an electrostatic clamp according to some aspects of the present disclosure or portion(s) thereof. The operations described with reference to example method 900 can be performed by, or according to, any of the systems, apparatuses, components, techniques, or combinations thereof described herein, such as those described with reference to FIGS. 1-8 above and FIG. 10 below.

At operation 902, the method can include forming a dielectric layer (e.g., dielectric layer 502, 602, 702, 802) that includes a plurality of burls (e.g., plurality of burls 504, 604, 702, 804) for supporting an object (e.g., object 506). In some aspects, the forming of the dielectric layer can be accomplished using suitable mechanical or other methods and include forming the dielectric layer in accordance with any aspect or combination of aspects described with reference to FIGS. 1-8 above and FIG. 10 below.

At operation 904, the method can include forming an electrostatic layer (e.g., electrostatic layer 508, 512, 608, 612, 712, 812) that includes, or is associated with, one or more electrodes (e.g., one or more electrodes 510, 610, 710, 810A, 810B). In some aspects, the forming of the electrostatic layer can be accomplished using suitable mechanical or other methods and include forming the electrostatic layer in accordance with any aspect or combination of aspects described with reference to FIGS. 1-8 above and FIG. 10 below.

At operation 906, the method can include generating, using the electrostatic layer, an electrostatic force to electrostatically clamp the object to the plurality of burls in response to an application of one or more voltages to the one or more electrodes. In some aspects, a first magnitude of the electrostatic force in a first region (e.g., region 520, 620, 720, 820) of the dielectric layer can be different than a second magnitude of the electrostatic force in a second region (e.g., region 522, 622, 624, 626, 722, 822) of the dielectric layer. In some aspects, the electrostatic force can include an electrostatic clamp pressure, and a first magnitude of the electrostatic clamp pressure in the first region of the dielectric layer can be greater than a second magnitude of the electrostatic clamp pressure in the second region of the dielectric layer. In some aspects, the generating of the electrostatic force can be accomplished using suitable mechanical or other methods and include generating the electrostatic force in accordance with any aspect or combination of aspects described with reference to FIGS. 1-8 above and FIG. 10 below.

Optionally, in some aspects, the forming of the electrostatic layer can include forming an electrostatic sheet (e.g., electrostatic sheet 514) that includes a plurality of apertures (e.g., plurality of apertures 516) that receive the plurality of burls such that the plurality of burls line up with the plurality of apertures. In such aspects, the method can further include mounting the electrostatic sheet to the dielectric layer.

Optionally, in some aspects, the forming of the dielectric layer can include forming the plurality of burls on a first glass substrate, and the forming of the electrostatic layer can include forming the electrostatic layer on a second glass substrate. In such aspects, the method can further include mounting the electrostatic layer to the dielectric layer such that the electrostatic layer is disposed vertically between the first glass substrate and the second glass substrate.

Optionally, in some aspects, the method can further include disposing the first region of the dielectric layer horizontally adjacent to one or more of the plurality of burls, and disposing the second region of the dielectric layer horizontally between two or more of the plurality of burls but not horizontally adjacent to the two or more of the plurality of burls.

Optionally, in some aspects, the forming of the electrostatic layer can include forming a first portion of the one or more electrodes in a first horizontal plane (e.g., as shown in region 620), and the forming of the electrostatic layer can include forming a second portion of the one or more electrodes in a second horizontal plane (e.g., as shown in region 622, 624, 626) different from the first horizontal plane.

Optionally, in some aspects, the forming of the dielectric layer can include forming the first region of the dielectric layer to a first thickness (e.g., as shown in region 720), and the forming of the dielectric layer can further include forming the second region of the dielectric layer to a second thickness (e.g., as shown in region 722) different from the first thickness. For example, the forming of the dielectric layer can include depositing or thermally growing and then patterning another dielectric layer (e.g., dielectric layer 708) on the dielectric layer (e.g., to form the increased thickness shown in region 720 and region 724, and to form the decreased thickness shown in region 722).

Optionally, in some aspects, the forming of the electrostatic layer can include forming a first electrode in a first area (e.g., a portion of modified electrode 810B shown in region 820) vertically adjacent to the first region of the dielectric layer, and the forming of the electrostatic layer can further include removing, by laser irradiation (e.g., laser irradiation 830), a second electrode from a second area (e.g., area 811 shown in region 822) vertically adjacent to the second region of the dielectric layer.

FIG. 10 is another example method 1000 for manufacturing (or, in some aspects, refurbishing) an electrostatic clamp according to some aspects of the present disclosure or portion(s) thereof. The operations described with reference to example method 1000 can be performed by, or according to, any of the systems, apparatuses, components, techniques, or combinations thereof described herein, such as those described with reference to FIGS. 1-9 above.

At operation 1002, the method can include receiving a wafer clamp (e.g., wafer clamp 500, 600, 700, 800). The wafer clamp can include a dielectric layer (e.g., dielectric layer 502, 602, 702, 802) that includes a plurality of burls (e.g., plurality of burls 504, 604, 702, 804) configured to support an object (e.g., object 506). The wafer clamp can further include an electrostatic layer (e.g., electrostatic layer 508, 512, 608, 612, 712, 812) that includes one or more electrodes (e.g., one or more electrodes 510, 610, 710, 810A, 810B). In some aspects, the receiving of the wafer clamp can be accomplished using suitable mechanical or other methods and include receiving the wafer clamp in accordance with any aspect or combination of aspects described with reference to FIGS. 1-9 above.

At operation 1004, the method can include removing, by laser irradiation (e.g., laser irradiation 830), one or more portions (e.g., area 811) of the one or more electrodes of the electrostatic layer. In some aspects, the electrostatic layer can be configured to generate an electrostatic force to electrostatically clamp the object to the plurality of burls in response to an application of one or more voltages to the one or more electrodes. In some aspects, a first magnitude of the electrostatic force in a first region (e.g., region 820) of the dielectric layer can be different than a second magnitude of the electrostatic force in a second region (e.g., region 822) of the dielectric layer. In some aspects, the first region of the dielectric layer can be disposed horizontally adjacent to one or more of the plurality of burls, and the second region of the dielectric layer can be disposed horizontally between two or more of the plurality of burls but not horizontally adjacent to the two or more of the plurality of burls. In some aspects, the electrostatic force can include an electrostatic clamp pressure, and a first magnitude of the electrostatic clamp pressure in the first region of the dielectric layer can be greater than a second magnitude of the electrostatic clamp pressure in the second region of the dielectric layer. In some aspects, the removing of the one or more portions of the one or more electrodes of the electrostatic layer can include removing, by laser irradiation, an electrode from an area vertically adjacent to the second region of the dielectric layer. In some aspects, the removing of the one or more portions of the one or more electrodes of the electrostatic layer can be accomplished using suitable mechanical or other methods and include removing the one or more portions of the one or more electrodes of the electrostatic layer in accordance with any aspect or combination of aspects described with reference to FIGS. 1-9 above.

The embodiments may further be described using the following clauses:

1. An apparatus comprising:
a dielectric layer comprising a plurality of burls configured to support an object; and
an electrostatic layer comprising one or more electrodes;
wherein:
   the electrostatic layer is configured to generate an electrostatic force to electrostatically clamp the object to the plurality of burls in response to an application of one or more voltages to the one or more electrodes; and
   a first magnitude of the electrostatic force in a first region of the dielectric layer is different than a second magnitude of the electrostatic force in a second region of the dielectric layer.
      2. The apparatus of clause 1, wherein the electrostatic layer comprises an electrostatic sheet comprising a plurality of apertures configured to receive the plurality of burls such that the plurality of burls line up with the plurality of apertures of the electrostatic sheet.
      3. The apparatus of clause 1, further comprising:
another dielectric layer;
a first glass substrate comprising the dielectric layer; and
a second glass substrate comprising the electrostatic layer and the another dielectric layer;
wherein the electrostatic layer is disposed vertically between the dielectric layer and the another dielectric layer.
   4. The apparatus of clause 1, wherein:
the first region of the dielectric layer is disposed horizontally adjacent to one or more of the plurality of burls; and
the second region of the dielectric layer is disposed horizontally between two or more of the plurality of burls but not horizontally adjacent to the two or more of the plurality of burls.
   5. The apparatus of clause 1, wherein:
the electrostatic force comprises an electrostatic clamp pressure; and
a first magnitude of the electrostatic clamp pressure in the first region of the dielectric layer is greater than a second magnitude of the electrostatic clamp pressure in the second region of the dielectric layer.
   6. The apparatus of clause 1, wherein:
a first portion of the one or more electrodes of the electrostatic layer is disposed in a first horizontal plane; and
a second portion of the one or more electrodes of the electrostatic layer is disposed in a second horizontal plane different from the first horizontal plane.
   7. The apparatus of clause 1, wherein a first thickness of the first region of the dielectric layer is greater than a second thickness of the second region of the dielectric layer.
   8. The apparatus of clause 1, wherein:
the electrostatic layer comprises an electrode disposed vertically adjacent to the first region of the dielectric layer; and
the electrostatic layer comprises no electrode disposed vertically adjacent to the second region of the dielectric layer.
   9. A method comprising:
forming a dielectric layer comprising a plurality of burls for supporting an object;
forming an electrostatic layer comprising one or more electrodes; and
generating, using the electrostatic layer, an electrostatic force to electrostatically clamp the object to the plurality of burls in response to an application of one or more voltages to the one or more electrodes, wherein a first magnitude of the electrostatic force in a first region of the dielectric layer is different than a second magnitude of the electrostatic force in a second region of the dielectric layer.
   10. The method of clause 9, wherein:
the forming of the electrostatic layer comprises forming an electrostatic sheet comprising a plurality of apertures that receive the plurality of burls such that the plurality of burls line up with the plurality of apertures; and
the method further comprises mounting the electrostatic sheet to the dielectric layer.
   11. The method of clause 9, wherein:
the forming of the dielectric layer comprises forming the plurality of burls on a first glass substrate;
the forming of the electrostatic layer comprises forming the electrostatic layer on a second glass substrate; and
the method further comprises mounting the electrostatic layer to the dielectric layer such that the electrostatic layer is disposed vertically between the first glass substrate and the second glass substrate.
   12. The method of clause 9, further comprising:
disposing the first region of the dielectric layer horizontally adjacent to one or more of the plurality of burls; and
disposing the second region of the dielectric layer horizontally between two or more of the plurality of burls but not horizontally adjacent to the two or more of the plurality of burls.
   13. The method of clause 9, wherein:
the electrostatic force comprises an electrostatic clamp pressure; and
a first magnitude of the electrostatic clamp pressure in the first region of the dielectric layer is greater than a second magnitude of the electrostatic clamp pressure in the second region of the dielectric layer.
   14. The method of clause 9, wherein:
the forming of the electrostatic layer comprises forming a first portion of the one or more electrodes in a first horizontal plane; and
the forming of the electrostatic layer comprises forming a second portion of the one or more electrodes in a second horizontal plane different from the first horizontal plane.
   15. The method of clause 9, wherein:
the forming of the dielectric layer comprises forming the first region of the dielectric layer to a first thickness; and
the forming of the dielectric layer further comprises forming the second region of the dielectric layer to a second thickness different from the first thickness.
   16. The method of clause 9, wherein:
the forming of the electrostatic layer comprises forming a first electrode in a first area vertically adjacent to the first region of the dielectric layer; and
the forming of the electrostatic layer further comprises removing, by laser irradiation, a second electrode from a second area vertically adjacent to the second region of the dielectric layer.
   17. A method comprising:
receiving a wafer clamp, wherein the wafer clamp comprises:
   a dielectric layer comprising a plurality of burls configured to support an object; and
   an electrostatic layer comprising one or more electrodes; and
removing, by laser irradiation, one or more portions of the one or more electrodes of the electrostatic layer;
wherein:
   the electrostatic layer is configured to generate an electrostatic force to electrostatically clamp the object to the plurality of burls in response to an application of one or more voltages to the one or more electrodes; and
   a first magnitude of the electrostatic force in a first region of the dielectric layer is different than a second magnitude of the electrostatic force in a second region of the dielectric layer.
      18. The method of clause 17, wherein
the first region of the dielectric layer is disposed horizontally adjacent to one or more of the plurality of burls; and
the second region of the dielectric layer is disposed horizontally between two or more of the plurality of burls but not horizontally adjacent to the two or more of the plurality of burls.
   19. The method of clause 17, wherein
the electrostatic force comprises an electrostatic clamp pressure; and
a first magnitude of the electrostatic clamp pressure in the first region of the dielectric layer is greater than a second magnitude of the electrostatic clamp pressure in the second region of the dielectric layer.
   20. The method of clause 18, wherein the removing of the one or more portions of the one or more electrodes of the electrostatic layer comprises removing, by laser irradiation, an electrode from an area vertically adjacent to the second region of the dielectric layer.

Although specific reference may be made in this text to the use of lithographic apparatus in the manufacture of ICs, it should be understood that the lithographic apparatuses described herein can have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein can be processed, before or after exposure, in for example a track unit (a tool that applies a layer of resist to a substrate and develops the exposed resist), a metrology unit and/or an inspection unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

It is to be understood that the phraseology or terminology herein is for the purpose of description and not of limitation, such that the terminology or phraseology of the present specification is to be interpreted by those skilled in relevant art(s) in light of the teachings herein.

The term “substrate” as used herein describes a material onto which material layers are added. In some aspects, the substrate itself can be patterned and materials added on top of it can also be patterned, or can remain without patterning.

The examples disclosed herein are illustrative, but not limiting, of the embodiments of this disclosure. Other suitable modifications and adaptations of the variety of conditions and parameters normally encountered in the field, and which would be apparent to those skilled in the relevant art(s), are within the spirit and scope of the disclosure.

While specific aspects of the disclosure have been described above, it will be appreciated that the aspects can be practiced otherwise than as described. The description is not intended to limit the embodiments of the disclosure.

It is to be appreciated that the Detailed Description section, and not the Background, Summary, and Abstract sections, is intended to be used to interpret the claims. The Summary and Abstract sections may set forth one or more but not all example embodiments as contemplated by the inventor(s), and thus, are not intended to limit the present embodiments and the appended claims in any way.

Some aspects of the disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific aspects of the disclosure will so fully reveal the general nature of the aspects that others can, by applying knowledge within the skill of the art, readily modify and/or adapt for various applications such specific aspects, without undue experimentation, without departing from the general concept of the present disclosure. Therefore, such adaptations and modifications are intended to be within the meaning and range of equivalents of the disclosed aspects, based on the teaching and guidance presented herein.

The breadth and scope of the present disclosure should not be limited by any of the above-described example aspects or embodiments, but should be defined only in accordance with the following claims and their equivalents.

1. An apparatus comprising:
a dielectric layer comprising a plurality of burls configured to support an object; and
an electrostatic layer comprising one or more electrodes;
wherein:
the electrostatic layer is configured to generate an electrostatic force to electrostatically clamp the object to the plurality of burls in response to an application of one or more voltages to the one or more electrodes; and
a first magnitude of the electrostatic force in a first region of the dielectric layer is different than a second magnitude of the electrostatic force in a second region of the dielectric layer.

2. The apparatus of claim 1, wherein the electrostatic layer comprises an electrostatic sheet comprising a plurality of apertures configured to receive the plurality of burls such that the plurality of burls line up with the plurality of apertures of the electrostatic sheet.

3. The apparatus of claim 1, further comprising:
another dielectric layer;
a first glass substrate comprising the dielectric layer; and
a second glass substrate comprising the electrostatic layer and the another dielectric layer;
wherein the electrostatic layer is disposed vertically between the dielectric layer and the another dielectric layer.

4. The apparatus of claim 1, wherein:
the first region of the dielectric layer is disposed horizontally adjacent to one or more of the plurality of burls; and
the second region of the dielectric layer is disposed horizontally between two or more of the plurality of burls but not horizontally adjacent to the two or more of the plurality of burls.

5. The apparatus of claim 1, wherein:
the electrostatic force comprises an electrostatic clamp pressure; and
a first magnitude of the electrostatic clamp pressure in the first region of the dielectric layer is greater than a second magnitude of the electrostatic clamp pressure in the second region of the dielectric layer.

6. The apparatus of claim 1, wherein:
a first portion of the one or more electrodes of the electrostatic layer is disposed in a first horizontal plane;
a second portion of the one or more electrodes of the electrostatic layer is disposed in a second horizontal plane different from the first horizontal plane; and/or
a first thickness of the first region of the dielectric layer is greater than a second thickness of the second region of the dielectric layer.

7. The apparatus of claim 1, wherein:
the electrostatic layer comprises an electrode disposed vertically adjacent to the first region of the dielectric layer; and
the electrostatic layer comprises no electrode disposed vertically adjacent to the second region of the dielectric layer.

8. A method comprising:
forming a dielectric layer comprising a plurality of burls for supporting an object;
forming an electrostatic layer comprising one or more electrodes; and
generating, using the electrostatic layer, an electrostatic force to electrostatically clamp the object to the plurality of burls in response to an application of one or more voltages to the one or more electrodes, wherein a first magnitude of the electrostatic force in a first region of the dielectric layer is different than a second magnitude of the electrostatic force in a second region of the dielectric layer.

9. The method of claim 8, wherein:
the forming of the electrostatic layer comprises forming an electrostatic sheet comprising a plurality of apertures that receive the plurality of burls such that the plurality of burls line up with the plurality of apertures; and
the method further comprises mounting the electrostatic sheet to the dielectric layer.

10. The method of claim 8, wherein:
the forming of the dielectric layer comprises forming the plurality of burls on a first glass substrate;
the forming of the electrostatic layer comprises forming the electrostatic layer on a second glass substrate; and
the method further comprises mounting the electrostatic layer to the dielectric layer such that the electrostatic layer is disposed vertically between the first glass substrate and the second glass substrate.

11. The method of claim 8, wherein:
the forming of the electrostatic layer comprises forming a first portion of the one or more electrodes in a first horizontal plane; and
the forming of the electrostatic layer comprises forming a second portion of the one or more electrodes in a second horizontal plane different from the first horizontal plane.

12. The method of claim 8, wherein:
the forming of the dielectric layer comprises forming the first region of the dielectric layer to a first thickness; and
the forming of the dielectric layer further comprises forming the second region of the dielectric layer to a second thickness different from the first thickness.

13. The method of claim 8, wherein:
the forming of the electrostatic layer comprises forming a first electrode in a first area vertically adjacent to the first region of the dielectric layer; and
the forming of the electrostatic layer further comprises removing, by laser irradiation, a second electrode from a second area vertically adjacent to the second region of the dielectric layer.

14. A method comprising:
receiving a wafer clamp, wherein the wafer clamp comprises:
a dielectric layer comprising a plurality of burls configured to support an object; and
an electrostatic layer comprising one or more electrodes; and
removing, by laser irradiation, one or more portions of the one or more electrodes of the electrostatic layer;
wherein:
the electrostatic layer is configured to generate an electrostatic force to electrostatically clamp the object to the plurality of burls in response to an application of one or more voltages to the one or more electrodes; and
a first magnitude of the electrostatic force in a first region of the dielectric layer is different than a second magnitude of the electrostatic force in a second region of the dielectric layer.

15. The method of claim 14, wherein the removing of the one or more portions of the one or more electrodes of the electrostatic layer comprises removing, by laser irradiation, an electrode from an area vertically adjacent to the second region of the dielectric layer.
